(19) United States
(12) Patent Application Publication
(10) Pub. No.: US 2026/0123517 A1
(43) Pub. Date: Apr. 30, 2026

(54) VERTICAL WETTABLE FLANK FOR A TOP-SIDE PACKAGE

(71) Applicant: TEXAS INSTRUMENTS INCORPORATED, DALLAS, TX (US)

(72) Inventors: Jomari AUSTRIA, MABALACAT CITY (PH); Laura May Antoinette D. CLEMENTE, MABALACAT CITY (PH); Jeffrey S. SOLAS, ILOILO CITY (PH)

(21) Appl. No.: 18/933,485

(22) Filed: Oct. 31, 2024

(51) Int. Cl. H01L 23/31; H01L 21/3105; H01L 21/311; H01L 21/56; H01L 21/768; H01L 23/00; H01L 23/495; H01L 23/498

(52) U.S. Cl. CPC H10W 74/114; H10P 50/283; H10W 20/056; H10W 70/411; H10W 70/424; H10W 70/461; H10W 70/65; H10W 74/016; H10P 95/062; H10W 72/536; H10W 72/884; H10W 74/10; H10W 90/736; H10W 90/756

(57) ABSTRACT

A method includes providing an IC package having a lead and a die encapsulated in a mold compound. The mold compound extends from a top mold surface to a base mold surface of the IC package. The method also includes trenching the mold compound from the top mold surface to the lead to form a trench. The method further includes forming a vertical wettable flank by filling the trench with a conductive material.

### TECHNICAL FIELD

This description relates to forming vertical wettable flanks for a top-side integrated circuit package, such as a quad-flat no-leads (QFN) package.

### BACKGROUND

There are different integrated circuit (IC) package types available on the market that include conductive leads on the underside of the IC package for solder joints. Because the leads are not easily viewed or exposed, it is difficult to determine whether the IC package has been successfully bonded to another device. For example, it is difficult to determine if an IC package has been correctly soldered to a printed circuit board (PCB). A wettable flank design exposes the leads at the sidewalls of the IC package which enables optical inspection of the soldering. However, the leads being exposed at the sidewalls can be difficult to bond to. For example, the size and placement of devices is limited to the footprint of the device.

### SUMMARY

A first example is related to a method for forming vertical wettable flanks for an integrated circuit (IC) device. The method includes providing an IC package having a lead and a die encapsulated in a mold compound. The mold compound extends from a top mold surface to a base mold surface of the IC package. The method also includes trenching the mold compound from the top mold surface to the lead to form a trench. The method further includes forming a vertical wettable flank by filling the trench with a conductive material.

A second example is related to another method for forming vertical wettable flanks for an integrated circuit (IC) package. The method includes providing a lead frame that extends in a vertical direction from a bottom lead frame surface to a top lead frame surface. The lead frame includes a lead and a die attach pad separated in a horizontal direction approximately orthogonal to the vertical direction. The method also includes affixing a die to the die attach pad of the lead frame. The method further includes attaching a bond wire between the die and the lead of the lead frame. The method yet further includes encapsulating the bond wire, the lead, the die, and the die attach pad in a mold compound to form an IC package. The mold compound extends from a top mold surface to a base mold surface. The method includes forming a trench in the mold compound from the top mold surface to the top lead frame surface of the lead. The method also includes forming a vertical wettable flank in the trench by filling the trench with a conductive material.

A third example is related to a semiconductor device. The semiconductor device includes an IC package having a die, a lead, and a bond wire affixed to the die and the lead. The lead has a lead width in a horizontal direction. The IC device also includes a mold compound that encapsulates the die, the lead, and the bond wire. The mold compound extends from a top mold surface to a base mold surface. The IC device further includes a vertical wettable flank of a conductive material in the mold compound and contacting the lead. The vertical wettable flank has first flank sidewall opposite a second flank sidewall in the horizontal direction and is positioned within the lead width.

### BRIEF DESCRIPTION OF THE DRAWINGS

FIG. 1 illustrates a cross-sectional view of an example of an integrated circuit (IC) device.

FIG. 2 illustrates a perspective view of another example vertical wettable flank of an IC device.

FIGS. 3-14 illustrate example stages of a method of fabricating an IC device having a vertical wettable flank.

FIG. 15 illustrates a cross-sectional view of an example of an integrated circuit (IC) device with a flip chip configuration.

FIG. 16 illustrates a flowchart of an example method for fabricating an IC device having a vertical wettable flank.

### DETAILED DESCRIPTION

Interconnect(s) with wettable flanks for integrated circuit (IC) packages, such as quad-flat no-leads (QFN) and dual-flat no-leads (DFN), do not have leads protruding from the housing. Instead, wettable flanks refer to non-protruding leads or contact lands of an interconnect. The wettable flanks are manufactured in a manner that promotes wetting of solder to the leads when mounted to another device, such as a printed circuit board (PCB). Wettable flanks enable the formation of a solder fillet that is able to be visually inspected (e.g., via automated optical inspection (AOI)) to verify an acceptable solder joint was formed between the lead and the PCB. The interconnects of QFNs for high voltage products are usually downset lead frames or stacked substrates. Downset lead frames and stacked substrates are custom built based on the desired IC package and still suffer deficiencies. For example, the leads of a stacked substrate package are usually bare copper, which can cause reliability issues, such as corrosion. Furthermore, stacked substrates have to be designed with heat sink features to dissipate heat.

In the devices and methods described herein, a vertical wettable flank is formed from the interconnect to the top of the IC package. The vertical wettable flank provides electrical access through the top-side of the IC device. Therefore, devices that are bonded to the IC device are not limited to the footprint of the IC device, but can be built up vertically. Furthermore, rather than having to design a specific stacked substrate with a heat sink, the vertical wettable flank allows a routable lead frame to be used as the interconnect. Routable lead frames are more widely available, cost effective, and better at dissipating heat than stacked substrates. Additionally, stacked substrates typically have bare copper leads that are subject to corrosion. The conductive surfaces of the vertical wettable flanks can be plated with solderable materials to prevent corrosion.

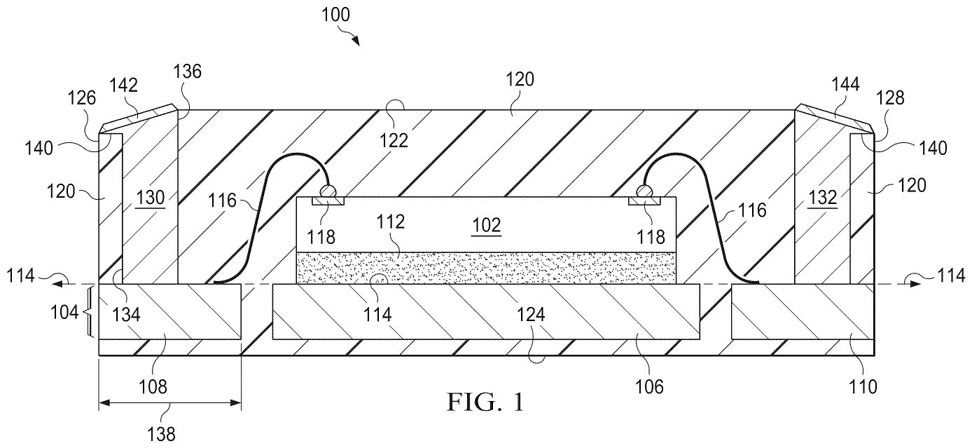

FIG. 1 illustrates an example of an IC device 100 that includes a die 102 mounted on an interconnect 104. The interconnect 104 is formed of an electrically conductive material, such as copper, palladium, gold, silver, or other appropriate conductive metal or metal alloy with similar properties. For example, the interconnect 104 is formed of a copper sheet. In one example, the interconnect 104 is a routable lead frame. The interconnect 104 includes a die attach pad 106 and a number of leads including a first lead 108 and a second lead 110.

The die 102 is mounted to the die attach pad 106 using a bond layer 112. The bond layer 112 is, for example, a layer of an adhesive agent, such as an epoxy resin. The bond layer 112 is affixed to a first surface 114 of the interconnect 104. The bond wires 116 affixed between the die 102 and the first lead 108 and the second lead 110, respectively. The bond wires 116 form an electrical connection between the die 102 and the leads 108, 110. In some examples, the die 102 includes landing pads 118. The landing pads 118 are formed of a conductive material. For example, the landing pads 118 are formed of copper and the interconnect 104, including the first lead 108 and the second lead 110, are formed of copper such that the bond wires 116 create a cooper-copper bond.

The die 102, the die attach pad 106, the first lead 108, the second lead 110, and the bond wires 116 are encapsulated in a mold compound 120. The mold compound 120 is formed of one or more insulating material, such as organic resins (e.g., epoxy), inorganic resins, and/or other suitable materials. For example, the mold compound 120 has a top mold surface 122 over the die 102. The top mold surface 122 is opposite a base mold surface 124. The mold compound 120 also forms a first package sidewall 126 opposite a second package sidewall 128 in a horizontal direction. Accordingly, the mold compound 120 encapsulates the IC device 100.

A first vertical wettable flank 130 and a second vertical wettable flank 132 are formed in the mold compound 120. The first vertical wettable flank 130 and the second vertical wettable flank 132 are formed of an electrically conductive material, such as copper, palladium, gold, silver, or other appropriate conductive metal or metal alloy with similar properties. The first vertical wettable flank 130 and the second vertical wettable flank 132 extend from the first lead 108 and the second lead 110, respectively, to the top mold surface 122 in a vertical direction, approximately orthogonal to the horizontal direction. For example, the first vertical wettable flank 130 contacts the first lead 108 at the first surface 114 and extends through the top mold surface 122. In one example, the conductive surfaces of the first vertical wettable flank 130 and the second vertical wettable flank 132 are continuous with the top mold surface 122.

The first vertical wettable flank 130 has a first flank sidewall 134 opposite a second flank sidewall 136 in the horizontal direction. The first flank sidewall 134 is proximate to the first package sidewall 126 and the second flank sidewall 136 is distal to the first package sidewall 126. The first lead 108 has a lead width 138. The first flank sidewall 134 and the second flank sidewall 136 extend toward the top mold surface 122 from the first lead 108 and are positioned within the lead width 138 of the first lead 108. For example, the first surface 114 of the interconnect 104 forms a plane. The lead width 138 defines a dimension of the first lead 108 in the plane. A flank width is dimension defined between the first flank sidewall 134 and the second flank sidewall 136. The first flank sidewall 134 and the second flank sidewall 136 are positioned such that the dimension of the flank width is at least bounded by the lead width 138. In some examples, the area of the first lead 108, at the plane defined at the first surface 114, surrounds the area of the first vertical wettable flank 130 at the plane.

In some examples, a first sidewall length of the first flank sidewall 134 is shorter than a second sidewall length of the second flank sidewall 136 in the vertical direction. The first flank sidewall 134 extends from the first surface 114 to an overhang 140. The overhang 140 extends from the first flank sidewall 134 to the first package sidewall 126. The overhang 140 is approximately parallel to the first surface 114 of the interconnect 104. In one example, the conductive surface of the first vertical wettable flank 130 is angled downward from the second flank sidewall 136 toward the shorter first flank sidewall 134 to the first package sidewall 126. In another example, the first flank sidewall 134 and the second flank sidewall 136 are approximately equal in length in the vertical direction. Accordingly, the conductive surface of the first vertical wettable flank 130 is approximately coplanar with a plane defined by the top mold surface 122.

For clarity, the examples are described with respect to the first vertical wettable flank 130. However, the second vertical wettable flank 132 may have similar features. For example, the conductive surface of the second vertical wettable flank 132 is also angled to slope downward toward the second package sidewall 128. In another example, the conductive surface of the first vertical wettable flank 130 is approximately coplanar with a plane defined by the top mold surface 122 and the conductive surface of the second vertical wettable flank 132 is angled to slope downward.

The leads and the vertical wettable flanks form a lead structure that provides electrical access to the die 102 through the top-side of the IC device 100. For example, a first lead structure includes the first lead 108 and the first vertical wettable flank 130 and a second lead structure includes the second lead 110 and the second vertical wettable flank 132. While two vertical wettable flanks are described the IC device 100 may include more or fewer vertical wettable flanks. For example, a vertical wettable flank may be formed for each lead of an IC device.

A first solderable metal layer 142 is formed over the conductive surface of the first vertical wettable flank 130 and a second solderable metal layer 144 is formed over the conductive surface of the second vertical wettable flank 132. The first solderable metal layer 142 and the second solderable metal layer 144 are formed of a solderable metal material to prevent corrosion of the conductive surface of the vertical wettable flanks 130, 132. Examples of the solderable metal material include various forms of nickel, palladium, tin, gold, etc. The first solderable metal layer 142 and the second solderable metal layer 144 are formed by applying the solderable metal material to the conductive surfaces of the first vertical wettable flank 130 and the second vertical wettable flank 132 in a deposition process. The first solderable metal layer 142 and the second solderable metal layer 144 do not extend over the mold compound 120.

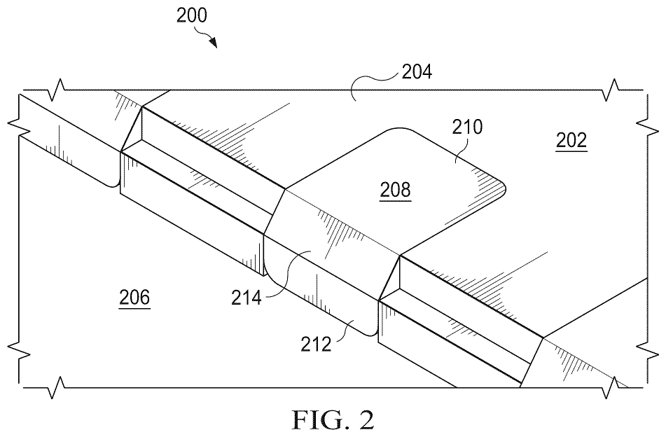

FIG. 2 illustrates a perspective view of another example vertical wettable flank of an IC device 200 (e.g., the IC device 100 of FIG. 1). The IC device 200 is encapsulated in a mold compound 202 (e.g., the mold compound 120 of FIG. 1) having a top mold surface 204 (e.g., the top mold surface 122 of FIG. 1) approximately orthogonal to a package sidewall 206 (e.g., the first package sidewall 126, the second package sidewall 128 of FIG. 1).

A vertical wettable flank 208 (e.g., the first vertical wettable flank 130, the second vertical wettable flank 132 of FIG. 1) is exposed in the mold compound 202. A conductive surface of the vertical wettable flank 208 has a horizontal surface 210 coplanar with the top mold surface 204. Additionally, the conductive surface of the vertical wettable flank 208 includes a vertical surface 212 coplanar with the package sidewall 206. In some examples, the conductive surface of the vertical wettable flank 208 further includes an angled surface 214 that connects the horizontal surface 210 and the vertical surface 212. In some examples, the horizontal surface 210, the vertical surface 212, and the angled surface 214 are coated with a solderable metal layer (e.g., the first solderable metal layer 142, the second solderable metal layer 144 of FIG. 1) to prevent corrosion of the conductive surface. Because the horizontal surface 210 of the vertical wettable flank 208 is coplanar with the top mold surface 204, devices can be bonded at the top-side of the IC device 200. Accordingly, the IC device 200 can be built in a vertical direction rather than being limited to the perimeter of the IC device 200 without the use of a stacked substrate.

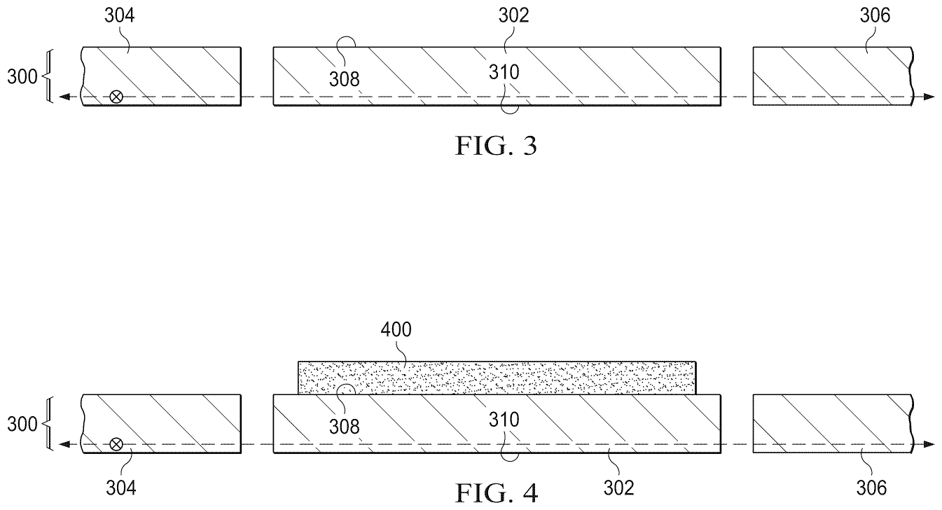

FIGS. 3-14 illustrate example stages of a method of fabricating an IC device, such as the IC device 100 of FIG. 1 or the IC device 200 of FIG. 2, having a vertical wettable flank (e.g., the first vertical wettable flank 130, the second vertical wettable flank 132 of FIG. 1, the vertical wettable flank 208 of FIG. 2). For purposes of simplification, FIGS. 3-14 employ the same reference numbers to denote the same structure.

FIG. 3 illustrates an example of a first stage of the method of fabricating an IC device. In the first stage, an interconnect 300 (e.g., the interconnect 104 of FIG. 1) is provided. As one example, the interconnect 300 includes a die attach pad 302 (e.g., the die attach pad 106 of FIG. 1), a first lead 304 (e.g., the first lead 108 of FIG. 1), and the second lead 306 (e.g., the second lead 110 of FIG. 1). The first lead 304 is separated from the second lead 306 by the die attach pad 302 in a horizontal direction. The interconnect 300 has a first surface 308 (e.g., the first surface 114 of FIG. 1) opposite a second surface 310 in the vertical direction approximately orthogonal to the horizontal direction. In some examples, the interconnect 300 is a routable lead frame.

FIG. 4 illustrates an example of a second stage of the method of fabricating the IC device. In the second stage, a bond layer 400 (e.g., the bond layer 112 of FIG. 1) is applied to at least a portion of the first surface 308 of the interconnect 300. For example, the bond layer 400 is applied to the die attach pad 302 of the interconnect 300. Accordingly, the bond layer 400 does not extend past the first surface 308 of the die attach pad 302. As one example, the bond layer 400 is a filmy adhesive agent, such as an epoxy resin.

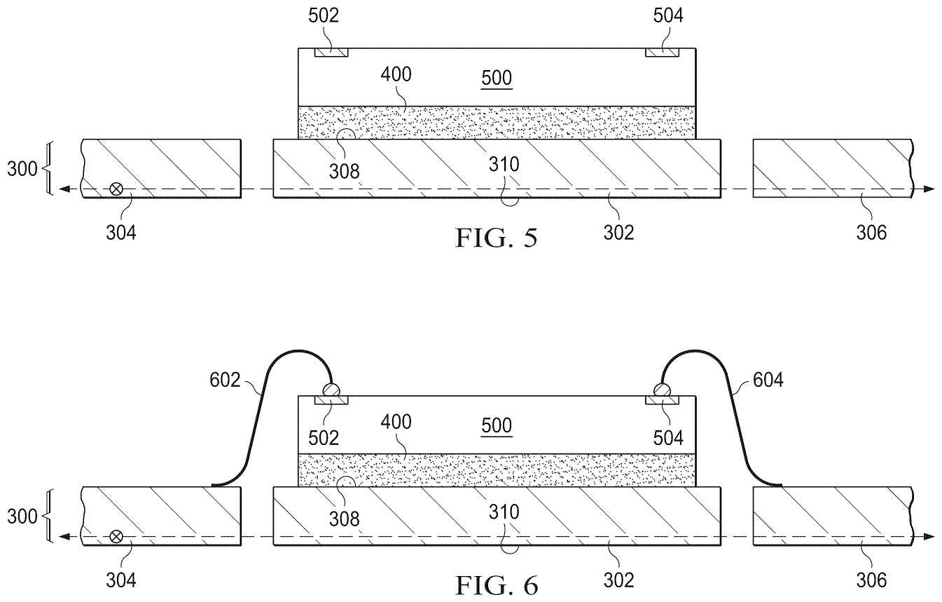

FIG. 5 illustrates an example of a third stage of the method of fabricating an IC device. In the third stage, a die 500 (e.g., the die 102 of FIG. 1) is affixed to the first surface 308 of the die attach pad 302 via the bond layer 400. In some examples, the die 500 includes a first landing pad 502 (e.g., the landing pad 118 of FIG. 1) and a second landing pad 504 (e.g., the landing pad 118 of FIG. 1). The first landing pad 502 and the second landing pad 504 are formed of a conductive material, such as copper.

FIG. 6 illustrates an example of a fourth stage of the method of fabricating the IC device. In the fourth stage, bond wires 602, 604 are affixed between the die 500 and the leads 304, 306. For example, a first bond wire 602 (e.g., the bond wire 116 of FIG. 1) is affixed at a first landing pad 502 of the die 500 and the first lead 304. A second bond wire 604 (e.g., the bond wire 116 of FIG. 1) is affixed at a second landing pad 504 of the die 500 and the second lead 306.

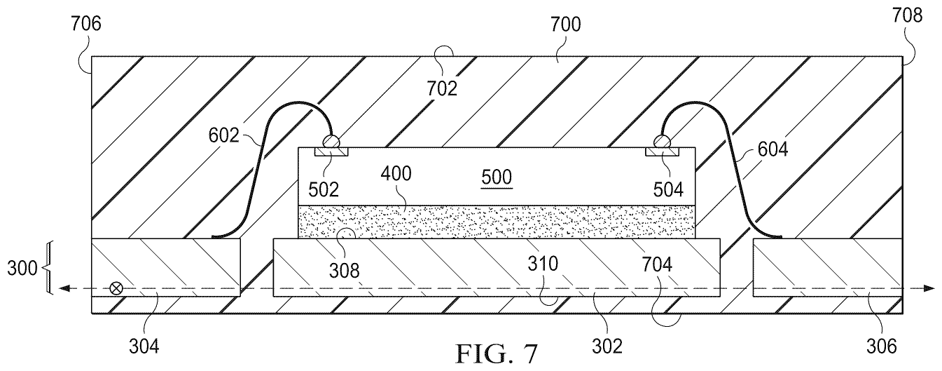

FIG. 7 illustrates an example of a fifth stage of the method of fabricating the IC device. In the fifth stage, the die attach pad 302, the first lead 304, the second lead 306, the die 500, the first bond wire 602, and the second bond wire 604 are at least partially encapsulated in a mold compound 700 (e.g., the mold compound 120 of FIG. 1, the mold compound 202 of FIG. 2). The mold compound 700 has a planar mold surface 702 opposite a base mold surface 704 (e.g., the base mold surface 124 of FIG. 1). The mold compound 700 also forms a first package sidewall 706 (e.g., the first package sidewall 126 of FIG. 1) opposite a second package sidewall 708 (e.g., the second package sidewall 128 of FIG. 1) in a horizontal direction. The mold compound 700 is formed of one or more insulating material, such as organic resins (e.g., epoxy), inorganic resins, and/or other suitable materials.

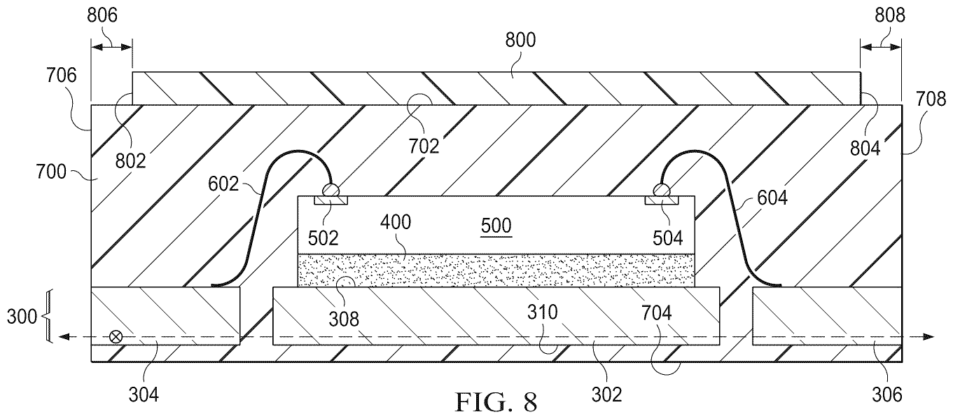

FIG. 8 illustrates an example of a sixth stage of the method of fabricating the IC device. In the sixth stage, a first photomask 800 is applied to the planar mold surface 702. The photomask 800 has a first edge 802 proximate to the first package sidewall 706. The first photomask 800 also has a second edge 804 proximate to the second package sidewall 708 and opposite the first edge 802. In some examples, the first edge 802 does not extend to the first package sidewall 706 and the second edge 804 does not extend to the second package sidewall 708. For example, the first edge 802 is laterally spaced from the first package sidewall 706 by a first lateral gap distance 806 in the horizontal direction. The second edge 804 is laterally spaced from the second package sidewall 708 by a second gap distance 808 in the horizontal direction. In some examples, the first edge 802 of the first photomask 800 is colinear with a predetermined location of a first flank sidewall (e.g., the first flank sidewall 134 of FIG. 1) that is proximate to the first package sidewall 706.

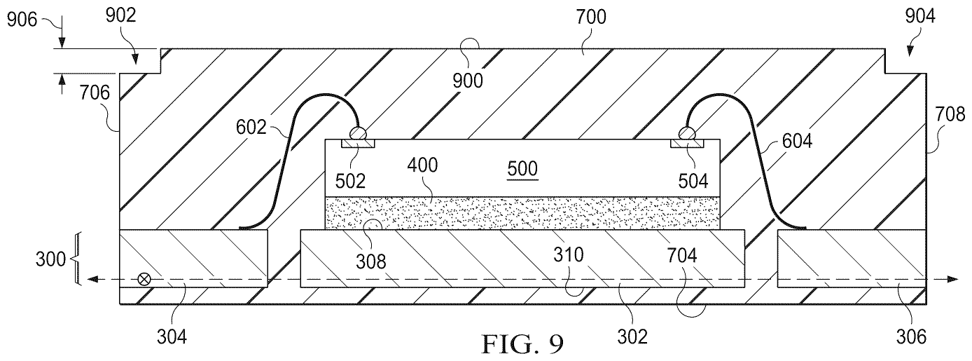

FIG. 9 illustrates an example of a seventh stage of the method of fabricating the IC device. In the seventh stage, the planar mold surface 702 is patterned with the first photomask 800 to form a patterned mold surface 900 and the first photomask 800 is removed. In one example, the first photomask 800 is opaque, blocking a portion of the planar mold surface 702 from irradiation used for patterning. The irradiated portions of the planar mold surface 702 are removed by applying a developer material. For example, a dry plasma etch is performed to remove the irradiated portions from the planar mold surface 702. The plasma etch may be a chlorine-based plasma etch or fluorine-based plasma etch. The patterned mold surface 900 includes a first notch 902 corresponding to the first lateral gap distance 806 and a second notch 904 corresponding to the second gap distance 808. The first notch 902 and the second notch 904 extend from the patterned mold surface 900 toward the base mold surface 704 by a patterned depth 906.

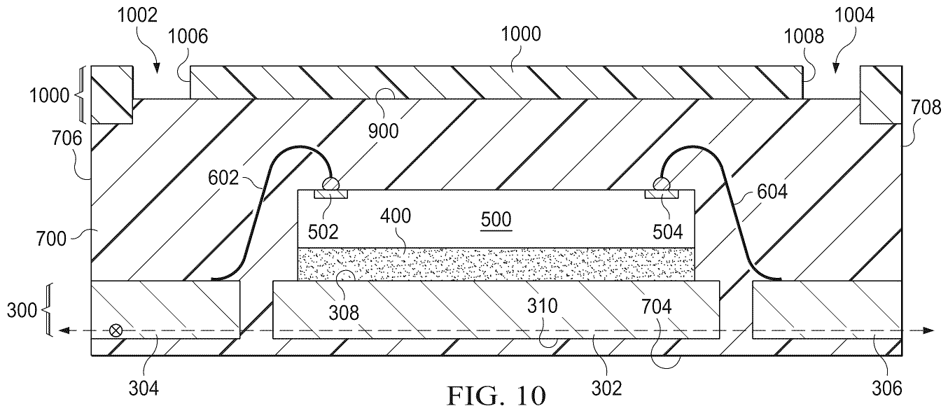

FIG. 10 illustrates an example of an eighth stage of the method of fabricating the IC device. In the eighth stage, a second photomask 1000 is applied to the patterned mold surface 900. The second photomask 1000 includes a first opening 1002 and a second opening 1004. The first opening 1002 is positioned over the first lead 304 and the second opening 1004 is positioned over the second lead 306. The first opening 1002 defines a first inner edge 1006 opposite a second inner edge 1008 defined by the second opening 1004. In some examples, the first inner edge 1006 of the second photomask 1000 is colinear with a predetermined location of a second flank sidewall (e.g., the second flank sidewall 136 of FIG. 1) that is distal to the first package sidewall 706.

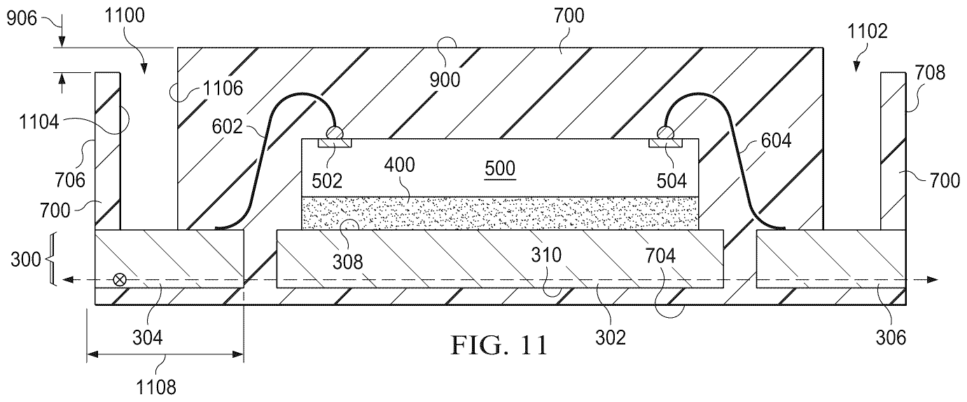

FIG. 11 illustrates an example of a ninth stage of the method of fabricating the IC device. In the ninth stage, the mold compound 700 is etched from the patterned mold surface 900 and the second photomask 1000 is removed. For example, the mold compound 700 is etched through the first opening 1002 to the first lead 304 to form a first trench 1100, and the mold compound 700 is etched through the second opening 1004 to the second lead 306 to form a second trench 1102.

The first trench 1100 has a first flank sidewall 1104 (e.g., the first flank sidewall 134 of FIG. 1) opposite a second flank sidewall 1106 (e.g., the second flank sidewall 136 of FIG. 1) in the horizontal direction. The first flank sidewall 1104 has a first sidewall length in the vertical direction. The second flank sidewall 1106 has a second sidewall length in the vertical direction. In some examples, a second sidewall length of the second flank sidewall is longer in the vertical direction than the first sidewall length of the first flank sidewall 1104 by the patterned depth 906. In other examples, the first flank sidewall 1104 and the second flank sidewall 1106 have approximately the same length.

The trenches 1100, 1102 are formed over leads 304, 306, respectively. The first lead 304 has a lead width 1108 in the horizontal direction. The first flank sidewall 1104 is proximate to the first package sidewall 706 and the second flank sidewall 1106 is distal to the first package sidewall 706. The first trench 1100 is positioned over the first lead 304 such that the first flank sidewall 1104 and the second flank sidewall 1106 are positioned within the lead width 1108. Similarly, the second trench 1102 is positioned within the lead width of the second lead 306.

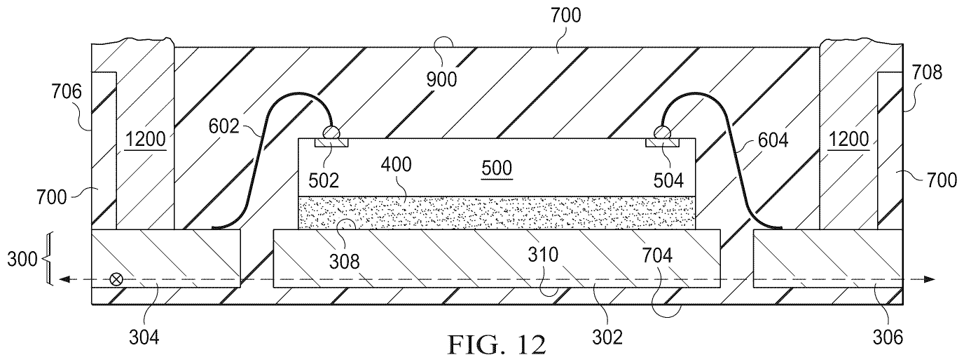

FIG. 12 illustrates an example of a tenth stage of the method of fabricating the IC device. In the tenth stage, the first trench 1100 and the second trench 1102 are filled with a conductive material 1200, such as copper, palladium, gold, silver, or other appropriate conductive metal or metal alloy with similar properties. The conductive material 1200 is overfilled in the first trench 1100 and the second trench 1102. For example, the conductive material 1200 extends in the first trench 1100 and the second trench 1102 from the first lead 304 and the second lead 306, respectively, over the patterned mold surface 900 in the vertical direction.

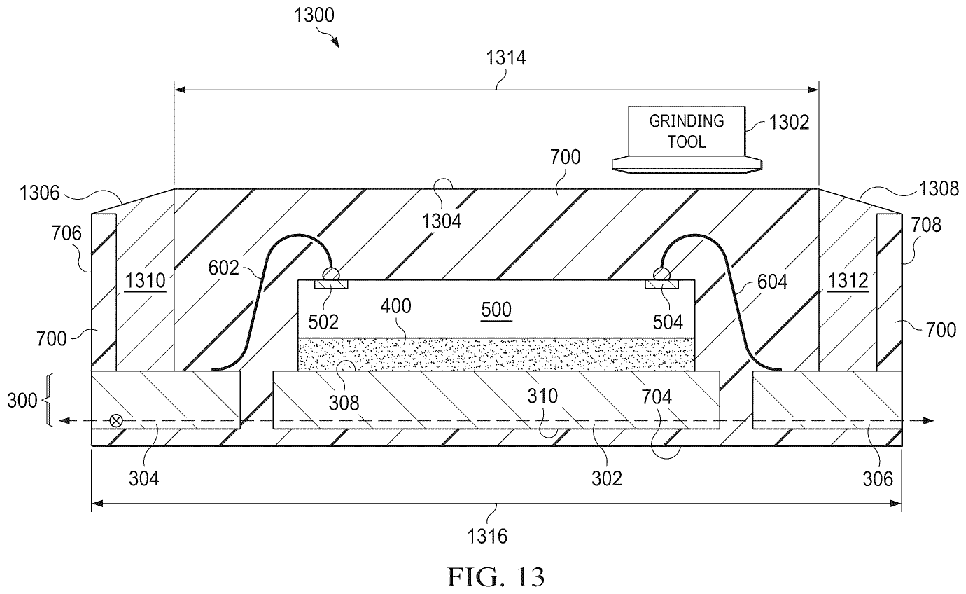

FIG. 13 illustrates an example of an eleventh stage of the method of fabricating the IC device. In the eleventh stage, the patterned mold surface 900 is ground to form a top mold surface 1300. The patterned mold surface 900 is ground with a grinding tool 1302 to remove additional material to create the top mold surface 1300. For example, a portion of the conductive material 1200 is removed so that the top mold surface is at least partially planar. The top mold surface 1300 includes an upper mold surface 1304 and exposes a first conductive surface 1306 and a second conductive surface 1308. The upper mold surface 1304 may be ground to be planar, while the conductive surfaces 1306, 1308 are ground to have a uniform angled surface. The first conductive surface 1306 is an upper surface of a first wettable flank 1310 (e.g., the first vertical wettable flank 130 of FIG. 1). The second conductive surface 1308 is an upper surface of a second wettable flank 1312 (e.g., the second vertical wettable flank 132 of FIG. 1).

Due to the trenching of the top mold surface 1300, a portion of the mold compound 700 is removed from the top mold surface 1300. Therefore, trenching causes the top mold surface 1300 to have an upper mold surface 1304 that is formed of the mold compound 700. The upper mold surface 1304 has an upper mold length 1314 that is shorter than a base mold length 1316 of the base mold surface 704 opposite the upper mold surface 1304. In some examples, the base mold length 1316 is measured from the first package sidewall 706 to the second package sidewall 708.

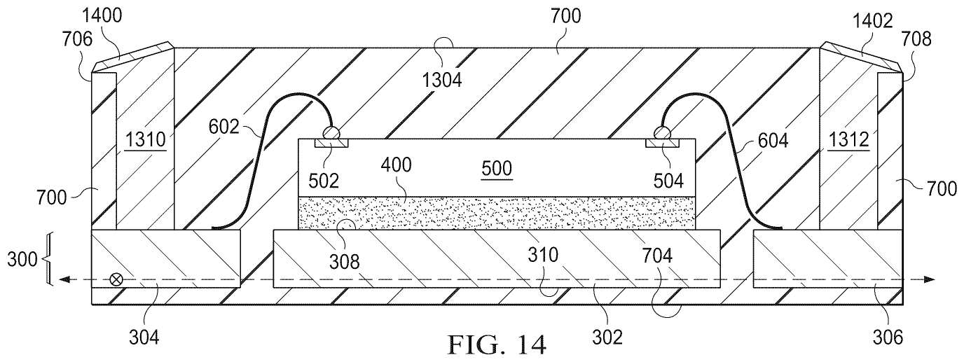

FIG. 14 illustrates an example of a twelfth stage of the method of fabricating the IC device. In the twelfth stage, a first solderable metal layer 1400 (e.g., the first solderable metal layer 142 of FIG. 1) is formed over the first vertical wettable flank 1310 and a second solderable metal layer 1402 (e.g., the second solderable metal layer 144 of FIG. 1) over the second vertical wettable flank 1312. The first solderable metal layer 1400 and the second solderable metal layer 1402 are formed solderable metal material (e.g., nickel, palladium, tin, gold, etc.) to prevent corrosion of the first conductive surface 1306 and the second conductive surface 1308, respectively, and to provide a solderable surface for effective bonding.

The first solderable metal layer 1400 and the second solderable metal layer 1402 may be applied in a deposition process, such as electroplating that utilizes an electric current. In one example, the first solderable metal layer 1400 and the second solderable metal layer 1402 are deposited using an immersion bath. The immersion bath utilizes a chemical reaction between the conductive material at the first conductive surface 1306 and the second conductive surface 1308 with the solderable metal material so that the first solderable metal layer 1400 and the second solderable metal layer 1402 are formed on the conductive surfaces but not the mold compound 700. In some examples, an electric current is not applied to the immersion bath. Accordingly, the solderable metal material coats the first conductive surface 1306, and a second conductive surface 1308 does not extend to the upper mold surface 1304.

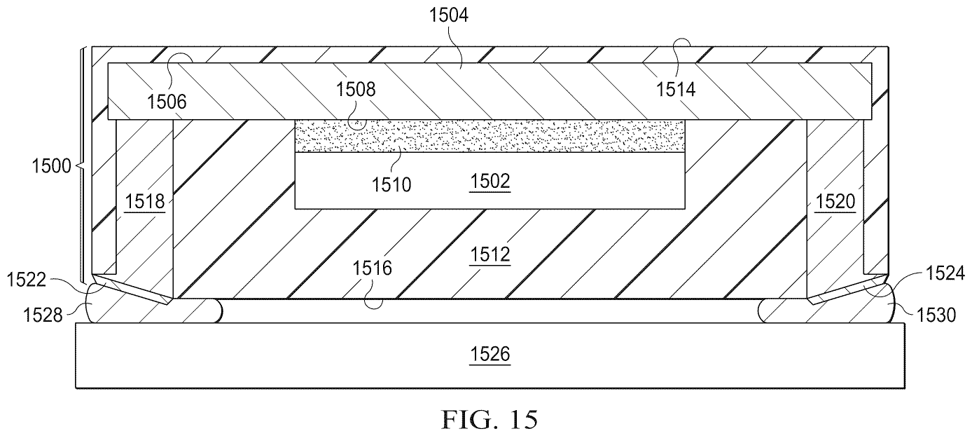

The above-illustrated embodiments of the present invention, and variations thereof, provide die-wafer packaging or multichip packaging. Although standard wire bonding configurations are shown, other configurations, including flip-chip configurations, may include vertical wettable flanks. FIG. 15 illustrates a cross-sectional view of an example of an integrated circuit (IC) device 1500 with a flip chip configuration. The IC device 1500 includes a die 1502 mounted on an interconnect 1504 (e.g., the interconnect 104 of FIG. 1, the interconnect 300 of FIG. 3). In some examples, the interconnect 1504 includes a die attach pad (e.g., the die attach pad 106, the die attach pad 302 of FIG. 3) having a first surface 1506 (e.g., the first surface 114 of FIG. 1, the first surface 308 of FIG. 3) opposite a second surface 1508 (e.g., the second surface 310 of FIG. 3) in the vertical direction approximately orthogonal to the horizontal direction. In some examples, the interconnect 1504 is a routable lead frame. The die 1502 is mounted to the second surface 1508 the interconnect 1504 using a bond layer 1510 (e.g., the bond layer 112 of FIG. 1, the bond layer 400 of FIG. 4). The die 1502 and the interconnect 1504 are encapsulated in a mold compound 1512 (e.g. the mold compound 120 of FIG. 1, the mold compound 700 of FIG. 7). The mold compound 1512 forms a top mold surface 1514 (e.g., the top mold surface 122 of FIG. 1, the top mold surface 204 of FIG. 2, the top mold surface 1300 of FIG. 13) opposite a base mold surface 1516 (e.g., the base mold surface 124 of FIG. 1).

A first vertical wettable flank 1518 (e.g., first vertical wettable flank 130, the vertical wettable flank 208 of FIG. 2, the first vertical wettable flank 1310) and a second vertical wettable flank 1520 (e.g., second vertical wettable flank 132, the vertical wettable flank 208 of FIG. 2, the second vertical wettable flank 1312) are formed in the mold compound 1512. The first vertical wettable flank 1518 and the second vertical wettable flank 1520 are formed of an electrically conductive material, such as copper, palladium, gold, silver, or other appropriate conductive metal or metal alloy with similar properties. The first vertical wettable flank 1518 and the second vertical wettable flank 1520 extend from the interconnect 1504 to the base mold surface 1516 in a vertical direction. For example, the first vertical wettable flank 1518 and the second vertical wettable flank 1520 contacts the die attach pad.

The conductive surfaces of the first vertical wettable flank 1518 and the second vertical wettable flank 1520 may be angled or coplanar with the base mold surface 1516. A first solderable metal layer 1522 (e.g., the first solderable metal layer 142 of FIG. 1, the first solderable metal layer 1400 of FIG. 14) is formed over the conductive surface of the first vertical wettable flank 1518 and a second solderable metal layer 1524 (e.g., the first solderable metal layer 144 of FIG. 1, the first solderable metal layer 1402 of FIG. 14) is formed over the conductive surface of the second vertical wettable flank 1520. The first solderable metal layer 1522 and the second solderable metal layer 1524 are formed of a solderable metal material to prevent corrosion of the conductive surface of the vertical wettable flanks 1518, 1520. Examples of the solderable metal material include various forms of nickel, palladium, tin, gold, etc. The first solderable metal layer 1522 and the second solderable metal layer 1524 are formed by applying the solderable metal material to the conductive surfaces of the first vertical wettable flank 1518 and the second vertical wettable flank 1520 in a deposition process.

The IC device 1500 is affixed to a device 1526 with a first solder bump 1528 and a second solder bump 1530. The device 1526 may be a workpiece or substrate, such as a printed circuit cable, or circuitry. The circuitry may include an active device or passive device. The first solder bump 1528 and the second solder bump 1530 are formed of a solderable metal material include various forms of nickel, palladium, tin, gold, etc. While two solder bumps are described, more or fewer may be utilized to affix the IC device 1500 to the device 1526. Accordingly, the vertical wettable flanks 1518, 1520 can be used in a flip chip configuration.

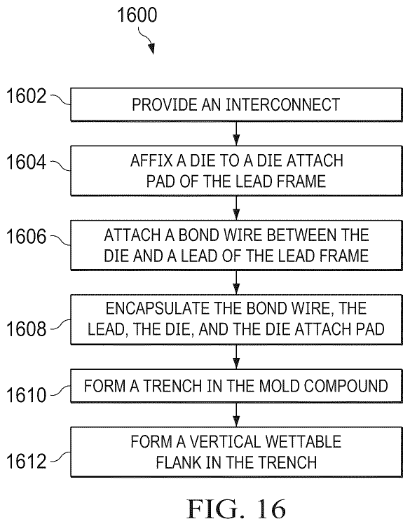

FIG. 16 illustrates a flowchart of an example method 1600 for fabricating an IC device having a vertical wettable flank. As one example, the IC device is a top side quad-flat no-leads (QFN) package.

At block 1602, the method 1600 includes providing an interconnect (e.g., the interconnect 104 of FIG. 1, the interconnect 300 of FIG. 3) that extends in a vertical direction from a bottom surface (e.g., the second surface 310 of FIG. 3) to a top surface (e.g., the first surface 308 of FIG. 3). The interconnect includes a lead (e.g., the first lead 108 and the second lead 110 of FIG. 1, the first lead 304 and the second lead 306 of FIG. 3) and a die attach pad (e.g., the die attach pad 106 of FIG. 1, the die attach pad 302 of FIG. 3) separated in a horizontal direction. As one example, the interconnect is provided as a routable lead frame formed from a conductive sheet.

At block 1604, the method 1600 includes affixing a die (e.g., the die 102 of FIG. 1, the die 500 of FIG. 5) to the die attach pad of the interconnect. For example, the die is attached to the interconnect using a bond layer (e.g., the bond layer 112 of FIG. 1, the bond layer 400 of FIG. 4). In an example, in which the interconnect is a routable lead frame, the routable lead frame includes a heat sink feature to dissipate heat. For example, the die attach pad draws heat away from the die.

At block 1606, the method 1600 includes attaching a bond wire (e.g., the bond wire 116 of FIG. 1, the first bond wire 602 and the second bond wire 604 of FIG. 6) between the die and the leads of the interconnect. The bond wires provide an electrical connection between the die and the interconnect.

At block 1608, the method 1600 includes encapsulating the bond wires, the leads, the die, and the die attach pad in a mold compound (e.g. the mold compound 120 of FIG. 1, the mold compound 700 of FIG. 7, the mold compound 1512 of FIG. 15) to form an IC device (e.g., the IC device 100 of FIG. 1, the IC device 200 of FIG. 2). The mold compound extends from a top mold surface (e.g., the top mold surface 122 of FIG. 1, the top mold surface 204 of FIG. 2, the top mold surface 1300 of FIG. 13, the top mold surface 1514 of FIG. 15) to a base mold surface (e.g., the base mold surface 124 of FIG. 1, the base mold surface 1516 of FIG. 15).

At block 1610, the method 1600 includes forming a trench (e.g., the first trench 1100 and the second trench 1102 of FIG. 11) in the mold compound 700. The trenches are formed using one or more etching techniques and may include utilizing a photomask (e.g., the first photomask 800 of FIG. 8, the second photomask 1000 of FIG. 10). The trenches are etched from the top mold surface to the top surface of one or more of the leads.

At block 1612, the method 1600 includes forming a vertical wettable flank (e.g., the first vertical wettable flank 130 and the second vertical wettable flank 132 of FIG. 1, the vertical wettable flank 208 of FIG. 2, the first vertical wettable flank 1310 and the second vertical wettable flank 1312 of FIG. 13, the first vertical wettable flank 1518 and the second vertical wettable flank 1520 of FIG. 15) in the trenches by filling the trenches with a conductive material (e.g., the conductive material 1200 of FIG. 12). For example, the conductive material is copper.

Together with the leads, the corresponding vertical wettable flanks form lead structures that provide electrical access through the top-side of the IC device. Therefore, device can be bonded to the top-side of the IC device rather than relying on the space around the footprint of the IC device, which is limited and decreasing as IC devices get smaller and smaller Furthermore, rather than having to design a specific stacked subframe with a heat sink, the vertical wettable flank allows a routable lead frame to be used as the interconnect even though the IC devices can be built up vertically. Routable lead frames have the additional benefits of being more widely available, cost effective, and better at dissipating heat than stacked substrates. Moreover, the conductive surfaces of the vertical wettable flanks can be plated with solderable materials to prevent corrosion.

What have been described above are examples. It is, of course, not possible to describe every conceivable combination of components or methodologies, but one of ordinary skill in the art will recognize that many further combinations and permutations are possible. Accordingly, the disclosure is intended to embrace all such alterations, modifications, and variations that fall within the scope of this application, including the appended claims. As used herein, the term “includes” means includes but not limited to, the term “including” means including but not limited to. The term “based on” means based at least in part on. Additionally, where the disclosure or claims recite “a,” “an,” “a first,” or “another” element, or the equivalent thereof, it should be interpreted to include one or more than one such element, neither requiring nor excluding two or more such elements.

In this description, unless otherwise stated, “about,” “approximately” or “substantially” preceding a parameter means being within +/−10 percent of that parameter. Modifications are possible in the described embodiments, and other embodiments are possible, within the scope of the claims.

Further, unless specified otherwise, “first”, “second”, or the like are not intended to imply a temporal aspect, a spatial aspect, an ordering, etc. Rather, such terms are merely used as identifiers, names, etc. for features, elements, items, etc. For example, a first channel and a second channel generally correspond to channel A and channel B or two different or two identical channels or the same channel. Additionally, “comprising”, “comprises”, “including”, “includes”, or the like generally means comprising or including, but not limited to.

It will be appreciated that several of the above-disclosed and other features and functions, or alternatives or varieties thereof, may be desirably combined into many other different systems or applications. Also, that various presently unforeseen or unanticipated alternatives, modifications, variations or improvements therein may be subsequently made by those skilled in the art which are also intended to be encompassed by the following claims.

What is claimed is:

1. A method of forming an integrated circuit (IC) device, comprising:
providing an IC package having a lead and a die encapsulated in a mold compound, the mold compound extending from a top mold surface to a base mold surface of the IC package,
trenching the mold compound from the top mold surface to the lead to form a trench; and
forming a vertical wettable flank by filling the trench with a conductive material.

2. The method of claim 1, wherein the lead has a lead width in a horizontal direction, and wherein the vertical wettable flank has first flank sidewall opposite a second flank sidewall in the horizontal direction that are positioned within the lead width.

3. The method of claim 2, wherein the first flank sidewall has a first sidewall length in a vertical direction approximately orthogonal to the horizontal direction and the second flank sidewall has a second sidewall length in the vertical direction longer than the first sidewall length.

4. The method of claim 2, wherein trenching the mold compound causes the top mold surface to have an upper mold surface with an upper mold length that is shorter than a base mold length of the base mold surface.

5. The method of claim 1, wherein the vertical wettable flank has a conductive surface, of the conductive material, in the top mold surface, the method further comprising:
plating the conductive surface of the vertical wettable flank to form a solderable metal layer.

6. The method of claim 5, wherein plating the conductive surface includes immersing the IC package in a bath of solderable metal material.

7. The method of claim 1, wherein the lead is provided as a portion of a routable lead frame.

8. The method of claim 7, wherein the routable lead frame includes a heat sink feature to dissipate heat.

9. A method of forming an integrated circuit (IC) device, comprising:
providing an interconnect that extends in a vertical direction from a first surface to a second surface, wherein the interconnect includes a lead and a die attach pad separated in a horizontal direction approximately orthogonal to the vertical direction;
affixing a die to the die attach pad of the interconnect;
attaching a bond wire between the die and the lead of the interconnect;
encapsulating the bond wire, the lead, the die, and the die attach pad in a mold compound to form an IC package, the mold compound extending from a top mold surface to a base mold surface,
forming a trench in the mold compound from the top mold surface to the first surface of the lead; and
forming a vertical wettable flank in the trench by filling the trench with a conductive material.

10. The method of claim 9, wherein the lead has a lead width, and wherein the vertical wettable flank has first flank sidewall opposite a second flank sidewall positioned within the lead width.

11. The method of claim 10, wherein the first flank sidewall has a first sidewall length in the vertical direction and the second flank sidewall has a second sidewall length in the vertical direction longer than the first sidewall length.

12. The method of claim 9, wherein the vertical wettable flank has a conductive surface, of the conductive material, in the top mold surface, the method further comprising:
plating the conductive surface of the vertical wettable flank to form a solderable metal layer.

13. The method of claim 12, wherein plating the conductive surface of the vertical wettable flank includes immersing the IC package in a bath of solderable metal material.

14. The method of claim 9, wherein the interconnect is a routable lead frame.

15. An integrated circuit (IC) device comprising:
an IC package having a die, a lead, and a bond wire affixed to the die and the lead, wherein the lead has a lead width in a horizontal direction;
a mold compound that encapsulates the die, the lead, and the bond wire, the mold compound extending from a top mold surface to a base mold surface; and
a vertical wettable flank of a conductive material in the mold compound contacting the lead, the vertical wettable flank having first flank sidewall opposite a second flank sidewall in the horizontal direction and positioned within the lead width.

16. The IC device of claim 15, wherein the first flank sidewall has a first sidewall length in a vertical direction, approximately orthogonal to the horizontal direction, and the second flank sidewall has a second sidewall length in the vertical direction longer than the first sidewall length such that a conductive surface of the vertical wettable flank is angled.

17. The IC device of claim 16, wherein an upper mold surface of the top mold surface has an upper mold length that is shorter than a base mold length of the base mold surface.

18. The IC device of claim 15, further comprising:
solderable metal layer over a conductive surface of the vertical wettable flank.

19. The IC device of claim 15, wherein the lead is provided by a routable lead frame having a heat sink feature.

20. The IC device of claim 15, wherein the IC device is a top side quad-flat no-leads (QFN) package.
